(19) United States
(12) Patent Application Publication
(10) Pub. No.: US 2021/0294218 A1
(43) Pub. Date: Sep. 23, 2021

(54) MODELING POST-EXPOSURE PROCESSES

(71) Applicant: ASML NETHERLANDS B.V., Veldhoven (NL)

(72) Inventors: Yongfa FAN, Sunnyvale, CA (US); Mu FENG, San Jose, CA (US); Leiwu ZHENG, San Jose, CA (US); Qian ZHAO, San Jose, CA (US); Jen-Shiang WANG, Sunnyvale, CA (US)

(73) Assignee: ASML NETHERLANDS B.V., Veldhoven (NL)

(21) Appl. No.: 16/324,933

(22) PCT Filed: Jul. 27, 2017
(86) PCT No.: PCT/EP2017/069068

§ 371 Date: Feb. 12, 2019

Related U.S. Application Data
(60) Provisional application No. 62/377,162, filed on Aug. 19, 2016.

(51) Int. Cl. G03F 7/20

(52) U.S. Cl. CPC G03F 7/705; G03F 7/70433; G03F 7/70616

(57) ABSTRACT

A process to model post-exposure effects in patterning processes, the process including: obtaining values based on measurements of structures formed on one or more substrates by a post-exposure process and values of a pair of process parameters by which process conditions were varied; modeling, by a processor system, as a surface, correlation between the values based on measurements of the structures and the values of the pair of process parameters; and storing the model in memory.

### CROSS REFERENCE TO RELATED APPLICATIONS

This application claims priority of U.S. provisional application 62/377,162 which was filed on Aug. 19, 2016 and which is incorporated herein in its entirety by reference.

### BACKGROUND

### Field

The present disclosure relates generally to patterning processes like those used to manufacture integrated circuits and, more specifically, to modeling processes occurring after resist is selectively exposed to energy.

### Description of the Related Art

Patterning processes take many forms. Examples include photolithography, electron-beam lithography, imprint lithography, inkjet printing, directed self-assembly, and the like. Often these processes are used to manufacture relatively small, highly-detailed components, such as electrical components (like integrated circuits or photovoltaic cells), optical components (like digital mirror devices or waveguides), and mechanical components (like accelerometers or microfluidic devices).

Often patterning processes are followed by various types of subtractive processes, such as dry etches or wet etches. In many cases, the patterning process applies a temporary patterned layer over a layer to be etched, and the temporary patterned layer selectively exposes the underlying layer to the etch, thereby transferring the pattern to the underlying layer.

In some cases, various effects cause the temporary patterned layer or etches to yield structures having dimensions different from targeted dimensions. These results can, in some cases, effect device performance or yield, or serve to impose undesirable constraints on process windows or design choices.

### SUMMARY

The following is a non-exhaustive listing of some aspects of the present techniques. These and other aspects are described in the following disclosure.

Some aspects include a process to model post-exposure effects in patterning processes, the process including: obtaining, with one or more processors, values based on measurements of structures formed on one or more substrates by a post-exposure process and values of a first pair of process parameters by which process conditions were varied; modeling, with one or more processors, as a surface, correlation between the values based on measurements of the structures and the values of the first pair of process parameters; and storing, with one or more processors, the model in memory.

Some aspects include a tangible, non-transitory, machine-readable medium storing instructions that when executed by a data processing apparatus cause the data processing apparatus to perform operations including the above-mentioned process.

Some aspects include a system, including: one or more processors; and memory storing instructions that when executed by the processors cause the processors to effectuate operations of the above-mentioned process.

### BRIEF DESCRIPTION OF THE DRAWINGS

The above-mentioned aspects and other aspects of the present techniques will be better understood when the present application is read in view of the following figures in which like numbers indicate similar or identical elements:

FIG. 1 is a block diagram of a lithography system;

FIG. 2 is a block diagram of a pipeline of simulation models of patterning processes;

FIG. 3 a flow chart of an example of a process to model post-exposure processes in accordance with some embodiments of the present techniques;

FIG. 4 illustrates an example of three-dimensional observed data in which process parameters in two dimensions are varied and resulting bias in a third dimension is measured after a given post-exposure process;

FIG. 5 illustrates an example of a convex hull in the process parameter dimensions and bounding values of process parameters that yielded the measured bias of FIG. 4 and a surface defined by points within the convex hull with interpolated measured bias values for quantized process parameters values;

FIG. 6 illustrates the surface of FIG. 5 after application of a two-dimensional smoothing filter;

FIG. 7 illustrates an extrapolated three-dimensional surface resulting from the data of FIG. 6;

FIG. 8 illustrates an example of a process by which the above describe model may be used to predict amounts of bias resulting from post-exposure processes and those predictions may be used to adjust patterning processes to counteract the effects of the bias;

FIG. 9 is a block diagram of an example computer system;

FIG. 10 is a schematic diagram of another lithography system;

FIG. 11 is a schematic diagram of another lithography system;

FIG. 12 is a more detailed view of the system in FIG. 11; and

FIG. 13 is a more detailed view of the source collector module SO of the system of FIGS. 11 and 12.

While the invention is susceptible to various modifications and alternative forms, specific embodiments thereof are shown by way of example in the drawings and will herein be described in detail. The drawings may not be to scale. It should be understood, however, that the drawings and detailed description thereto are not intended to limit the invention to the particular form disclosed, but to the contrary, the intention is to cover all modifications, equivalents, and alternatives falling within the spirit and scope of the present invention as defined by the appended claims.

### DETAILED DESCRIPTION OF CERTAIN EMBODIMENTS

To mitigate the problems described herein, the inventors had to both invent solutions and, in some cases just as importantly, recognize problems overlooked (or not yet foreseen) by others in the field of computational analysis of design layouts. Indeed, the inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

Some systems calibrate a model of post-exposure processes based on empirical measurements. This may include running a test wafer with different process parameters, measuring resulting critical dimension bias after post-exposure processes, and calibrating the model to the measured results. Often such models are expressed as closed form equations that are functions of the process parameters.

Many techniques for modeling post-exposure processes do not account for interactions between modeling terms. As a result, such models often fail to accurately predict the shape of resulting structures on substrates, particularly where such interactions are relatively strong. At the same time, many techniques for modeling complex interactions, such as closed form equations with higher order terms, fail to adequately generalize from training data and over-fit test results, yielding predictions that can be inaccurate, particularly when spurious measurements occur in calibration data sets. (Such tradeoffs should not be read to imply that all embodiments are inconsistent with either of these approaches or that any subject matter is disclaimed.)

Some embodiments mitigate some of these issues with models that include an ordered collection of three-dimensional surfaces. The surfaces may indicate bias amounts on a z-axis, and those values may be accessible via a pair of modeling parameters on the x and y axis. Some embodiments may predict a total amount of bias after resist development or after etch for a set of modeling parameters by accessing the z-value in each of these surfaces for the corresponding parameter coordinates, and then summing the z-values among the surfaces to obtain a total predicted bias.

In some cases, the interactions to be modeled with surfaces are selected by ranking the modeling parameter according a configuration by an engineer, who may rank pairs of parameters according to known or expected strength of interaction. Or this can be determined empirically with principle component analysis. Some embodiments may iterate down the list, determining a surface indicating bias for one-pair of parameters, before determining a surface for the next pair of parameters. After the first surface, subsequent surfaces may account for bias un-accounted for by the higher-ranking pairs of process parameters (e.g., modeling as a surface an error between predictions from the sum of surfaces from higher ranking pairs of parameters). Some embodiments may include around five such surfaces, though lower latency models may include fewer, like less than three, and richer models may include more, like more than six.

Some variants may form higher dimensional surfaces, e.g., accounting for three way (or higher) interactions of process parameters, in the models. Some variants may interpolate between measurement data to form the surfaces, and some embodiments may smooth the interpolated surfaces. Some embodiments may also reject outliers, e.g., more than three standard deviations from a local mean. Some embodiments may cross validation resulting models on withheld subsets of calibration data.

These techniques are best understood in view of an example of a type of patterning process by which a design layout may be patterned on a substrate, as many of the computational analyses are designed to mitigate biases and other artifacts potentially otherwise introduced in this process.

A lithographic projection apparatus can be used, for example, in the manufacture of integrated circuits (ICs). In such a case, a patterning device (e.g., a mask) may specify a pattern corresponding to a layer of the IC (“design layout”), such as a via layer, an interconnect layer, or gate layer, or the like. This pattern, often forming part of a circuit, may be transferred onto a target portion (e.g. one or more dies in an exposure field) on a substrate (e.g., a silicon wafer) that has been coated with a layer of radiation-sensitive material (e.g., “resist”). Transfer techniques include irradiating the target portion through the circuit pattern on the patterning device. Often, a single substrate contains a plurality of adjacent target portions to which the circuit pattern is transferred successively by the lithographic projection apparatus, one target portion at a time. In one type of lithographic projection apparatuses, the pattern on the entire patterning device is transferred onto one target portion in one go; such an apparatus is commonly referred to as a stepper. In an alternative apparatus, commonly referred to as a step-and-scan apparatus, a projection beam scans over the patterning device in a given reference direction (the “scanning” direction) while synchronously moving the substrate parallel or anti-parallel to this reference direction. Different portions of the circuit pattern on the patterning device may be transferred to one target portion progressively. Often, the lithographic projection apparatus will have a magnification factor M (generally <1), so the speed F at which the substrate is moved will be a factor M times that at which the projection beam scans the patterning device. More information about examples of some lithographic devices are described, for example, by U.S. Pat. No. 6,046,792, incorporated herein by reference.

A variety of processes may occur before and after exposure. Prior to transferring the pattern from the patterning device to the substrate, the substrate may undergo various procedures, such as priming, resist coating and a soft bake. After exposure, the substrate may be subjected to other procedures, such as a post-exposure bake (PEB), development, a hard bake and measurement/inspection of the transferred circuit pattern. This array of procedures is used as a basis to make an individual layer of a device, e.g., an IC. The substrate may then undergo various processes such as etching, ion-implantation or diffusion (doping), metallization, oxidation, chemical-mechanical polishing, etc., to form a layer of the device. If several layers are required in the device, then variations on this procedure may be repeated for each layer, often with a different pattern specified by a different patterning device at each layer. Eventually, a device may be formed in each target portion on the substrate. These devices may then be separated from one another by a technique such as dicing or sawing, whence the individual devices can be mounted on a carrier, connected to pins, ball-grid arrays, etc. Or some embodiments may encapsulate devices before simulation.

As noted, lithography is a step in the manufacturing of ICs, where patterns formed on substrates define functional elements of the ICs, such as microprocessors, memory chips etc. Similar lithographic techniques are also used in the formation of flat panel displays, micro-electro mechanical systems (MEMS) and other devices.

As semiconductor manufacturing processes continue to advance, the dimensions of functional elements have continually been reduced while the amount of functional elements, such as transistors, per device has been steadily increasing over decades, following a trend commonly referred to as “Moore's law.” Often, layers of devices are manufactured using lithographic projection apparatuses that project a design layout onto a substrate using illumination from a deep-ultraviolet illumination source, creating individual functional elements having dimensions well below 100 nm, i.e., less than half the wavelength of the radiation from the illumination source (e.g., a 193 nm illumination source).

This process in which features with dimensions smaller than the classical resolution limit of a lithographic projection apparatus are printed, is commonly known as low-k1 lithography, according to the resolution formula CD=k1×λ/NA, where λ is the wavelength of radiation employed (often 248 nm or 193 nm for photolithography), NA is the numerical aperture of projection optics in the lithographic projection apparatus, CD is the “critical dimension”—generally the smallest feature size printed—and k1 is an empirical resolution factor. In general, the smaller k1 the more difficult it becomes to reproduce a pattern on the substrate that resembles the shape and dimensions planned by a circuit designer in order to achieve particular electrical functionality and performance.

To overcome these difficulties, fine-tuning steps are often applied to the lithographic projection apparatus or design layout. These include, for example, optimization of NA and optical coherence settings, customized illumination schemes, use of phase shifting patterning devices, optical proximity correction (OPC, sometimes also referred to as “optical and process correction”) in the design layout, or other methods generally defined as “resolution enhancement techniques” (RET). The term “projection optics” as used herein should be broadly interpreted as encompassing various types of optical systems, including refractive optics, reflective optics, apertures and catadioptric optics, for example. Examples of “projection optics” include components operating according to any of these design types for directing, shaping or controlling the projection beam of radiation, collectively or singularly. Examples of “projection optics” include optical components in a lithographic projection apparatus, no matter where the optical component is located on an optical path of the lithographic projection apparatus. Projection optics may include optical components for shaping, adjusting or projecting radiation from the source before the radiation passes the patterning device, or optical components for shaping, adjusting or projecting the radiation after the radiation passes the patterning device. The projection optics generally exclude the source and the patterning device.

Although specific reference may be made in this text to the manufacture of ICs, it should be explicitly understood that the description herein has many other possible applications. For example, it may be employed in the manufacture of integrated optical systems, guidance and detection patterns for magnetic domain memories, liquid crystal display panels, thin film magnetic heads, etc. The skilled artisan will appreciate that, in the context of such alternative applications, any use of the terms “reticle,” “wafer,” or “die” in this text should be considered as interchangeable with the more general terms “mask,” “substrate,” and “target portion,” respectively.

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm). In some embodiments, examples of “radiation” and “beam” also include electrical radiation, such as electron beams or ion beams, by which patterns are transferred.

The term “optimizing” and “optimization” as used herein refers to or means adjusting a lithographic projection apparatus, a lithographic process, etc. such that results or processes of lithography have more desirable characteristics, such as higher accuracy of projection of a design layout on a substrate, a larger process window, etc. Thus, the term “optimizing” and “optimization” as used herein refers to or means a process that identifies one or more values for one or more parameters that provide an improvement, e.g., a local optimum, in at least one relevant metric, compared to an initial set of one or more values for those one or more parameters. These terms do not require identifying a global optimum and can encompasses improvements short of a global optimum. In an embodiment, optimization steps can be applied iteratively to provide further improvements in one or more metrics. Steps in which an error function or loss function is minimized (e.g., reduced to, or at least closer to, a minimum) in an optimizing process should be read as generic to steps in which signs are reversed and a fitness function is maximized (e.g., increased to, or at least closer to, a maximum), and vice versa.

In some embodiments, the lithographic projection apparatus may be of a type having two or more tables (e.g., two or more substrate table, a substrate table and a measurement table, two or more patterning device tables, etc.). In such “multiple stage” devices a plurality of the multiple tables may be used concurrently, or preparatory steps may be carried out on one or more tables while one or more other tables are being used for exposures. Twin stage lithographic projection apparatuses are described, for example, in U.S. Pat. No. 5,969,441, incorporated herein by reference.

The patterning device referred to above may specify some or all of one or more design layouts (e.g., a portion of a design layout for double-patterning, or an entire layout). The design layout can be generated using CAD (computer-aided design) programs, this process often being referred to as EDA (electronic design automation). Most CAD programs follow a set of predetermined design rules in order to create functional design layouts/patterning devices. These rules are set by processing and design limitations. For example, design rules define the space tolerance between circuit elements (such as gates, capacitors, etc.), vias, or interconnect lines, so as to reduce the likelihood of the circuit devices or lines interacting with one another in a material, undesirable way. One or more of the design rule limitations may be referred to as “critical dimensions” (CD). A critical dimension of a circuit, in some contexts, refers to the smallest width of a line or hole or the smallest space between two lines or two holes. Thus, the CD determines the overall size and density of the designed circuit. Of course, one of the goals in integrated circuit fabrication is to faithfully reproduce the original circuit design on the substrate (via the patterning device).

The term “mask” or “patterning device” refers to a device that can be used to endow an incoming radiation beam with a patterned cross-section (which may unfold over time, e.g., in scanning or electron-beam lithography), corresponding to a pattern that is to be created in a target portion of the substrate; the term “light valve” can also be used in this context. Besides the classic mask (transmissive or reflective; binary, phase-shifting, hybrid, etc.), examples of other such patterning devices include:
a programmable mirror array. An example of such a device is a matrix-addressable surface having a viscoelastic control layer and a reflective surface. The basic principle behind such an apparatus is that (for example) addressed areas of the reflective surface reflect incident radiation as diffracted radiation, whereas unaddressed areas reflect incident radiation as undiffracted radiation. Using an appropriate filter, the said undiffracted radiation can be filtered out of the reflected beam, leaving only the diffracted radiation behind; in this manner, the beam becomes patterned according to the addressing pattern of the matrix-addressable surface. The required matrix addressing can be performed using suitable electronic means. More information on such mirror arrays can be gleaned, for example, from U.S. Pat. Nos. 5,296,891 and 5,523,193, which are incorporated herein by reference.
a programmable LCD array. An example of such a construction is given in U.S. Pat. No. 5,229,872, which is incorporated herein by reference.

Non-optical patterning devices include an electron beam modulator coupled to a data source for a design layout and configured to spatially modulate the beam according to the layout. Other examples include a mold for imprint lithography and an inkjet printer, e.g., with electrically conductive or insulative ink.

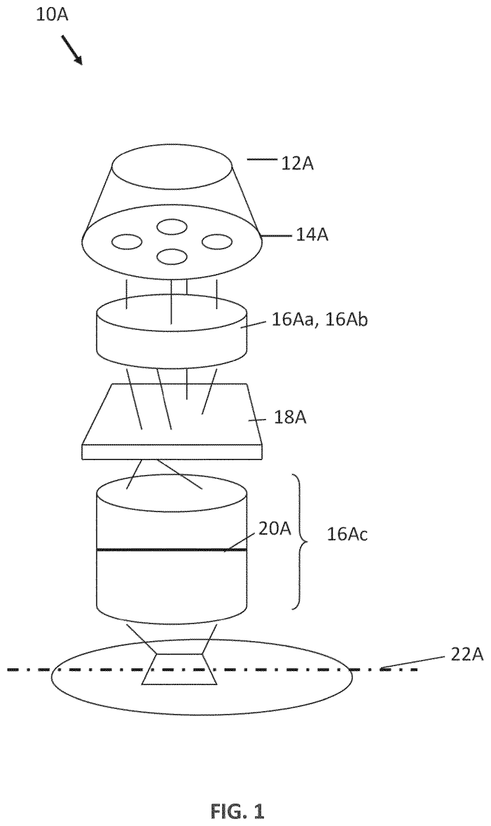

As a brief introduction, FIG. 1 illustrates an example of a lithographic projection apparatus 10A. Major components are a radiation source 12A, which may be a deep-ultraviolet excimer laser source or other type of source including an extreme ultra violet (EUV) source (as discussed above, the lithographic projection apparatus itself need not have the radiation source), illumination optics which define the partial coherence (denoted as sigma) and which may include optics 14A, 16Aa and 16Ab that shape radiation from the source 12A; a patterning device 14A; and transmission optics 16Ac that project an image of the patterning device pattern onto a substrate plane 22A. An adjustable filter or aperture 20A at the pupil plane of the projection optics may restrict the range of beam angles that impinge on the substrate plane 22A, where the largest possible angle defines the numerical aperture of the projection optics NA=n sin(Θmax), n is the Index of Refraction of the media between the last element of projection optics and the substrate, and Θmax is the largest angle of the beam exiting from the projection optics that can still impinge on the substrate plane 22A. The radiation from the radiation source 12A may not necessarily be at a single wavelength. Instead, the radiation may be at a range of different wavelengths. The range of different wavelengths may be characterized by a quantity called “imaging bandwidth,” “source bandwidth” or simply “bandwidth,” which are used interchangeably herein. A small bandwidth may reduce the chromatic aberration and associated focus errors of the downstream components, including the optics (e.g., optics 14A, 16Aa and 16Ab) in the source, the patterning device and the projection optics. However, that does not necessarily lead to a rule that the bandwidth should never be enlarged.

In an optimization process of a patterning process using a patterning system, a figure of merit of the system can be represented as a cost function. The optimization process may include finding a set of parameters (e.g., design variables and parameter settings) of the system that optimizes (e.g., minimizes or maximizes) the cost function. The cost function can have any suitable form depending on the goal of the optimization. For example, the cost function can be weighted root mean square (RMS) of deviations of certain characteristics (evaluation points) of the system with respect to the intended values (e.g., ideal values) of these characteristics; the cost function can also be the maximum of these deviations (e.g., worst deviation). “Evaluation points” may include any characteristics of the system, depending on the context.

The design variables of the system can be confined to finite ranges and may be interdependent due to practicalities of implementations of the system. In the case of a lithographic projection apparatus, the constraints are often associated with physical properties and characteristics of the hardware such as tunable ranges, or patterning device manufacturability design rules, and the evaluation points can include physical points on a resist image on a substrate, as well as non-physical characteristics such as dose and focus.

In some examples of a lithographic projection apparatus, a source provides illumination (or other types of radiation) to a patterning device and projection optics direct and shape the illumination, via the patterning device, onto a substrate. For example, projection optics may include at least some of the components 14A, 16Aa, 16Ab and 16Ac. An aerial image (AI) is the radiation intensity distribution at substrate level. A resist layer on the substrate is exposed and the aerial image is transferred to the resist layer as a latent “resist image” (RI) therein. The resist image (RI) can be defined as a spatial distribution of solubility of the resist in the resist layer. A resist model can be used to calculate the resist image from the aerial image, an example of which can be found in U.S. Patent Application Publication No. US 2009-0157360, the disclosure of which is hereby incorporated by reference in its entirety. The resist model is related to properties of the resist layer (e.g., only to these properties) (e.g., effects of chemical processes which occur during exposure, PEB and development). Optical properties of the lithographic projection apparatus (e.g., properties of the source, the patterning device and the projection optics) may dictate the aerial image. Since the patterning device used in the lithographic projection apparatus can be changed in some embodiments, it is often desirable to separate the optical properties of the patterning device from the optical properties of the rest of the lithographic projection apparatus including at least the source and the projection optics.

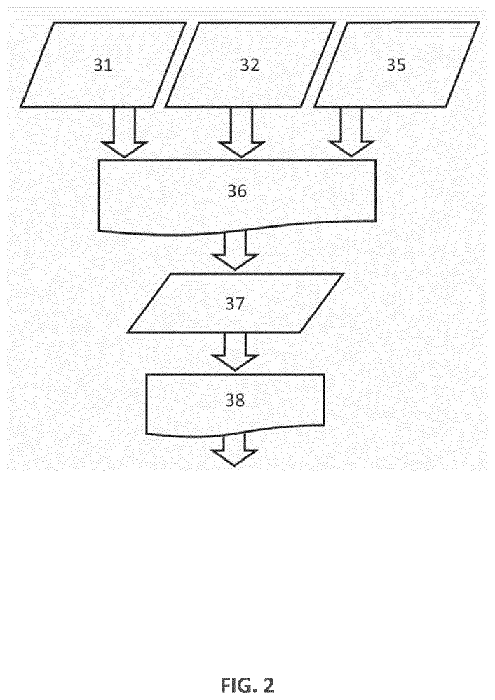

An exemplary pipeline for simulating patterning and subsequent subtractive processes is illustrated in FIG. 2. In this example, a source model 31 represents optical characteristics (including radiation intensity distribution, bandwidth and/or phase distribution) of the source. A projection optics model 32 represents optical characteristics (including changes to the radiation intensity distribution and/or the phase distribution caused by the projection optics) of the projection optics. A design layout model 35 represents optical characteristics (including changes to the radiation intensity distribution or the phase distribution caused by a given design layout 33) of a design layout, which is the representation of an arrangement of features on or formed by a patterning device. An aerial image 36 can be simulated from the design layout model 35, the projection optics model 32 and the design layout model 35. A resist image 38 can be simulated from the aerial image 36 using a resist model 37. Simulation of lithography can, for example, predict contours and CDs in the resist image. In some embodiments, the simulation may yield spatial dimensions of simulated patterned structures formed on a simulated substrate by a simulated process, such as line-widths, sidewall taper or curvature, via diameters, fillet radii, chamfer radii, surface roughness, interal stress or strain, overlay, etc.

In some embodiments, the source model 31 may represent the optical characteristics of the source that include, for example, NA settings, sigma (o) settings as well as any particular illumination shape (e.g. off-axis radiation sources such as annular, quadrupole, dipole, etc.). The projection optics model 32 may represent the optical characteristics of the projection optics, including aberration, distortion, one or more refractive indexes, one or more physical sizes, one or more physical dimensions, etc. The design layout model 35 may represent one or more physical properties of a physical patterning device, as described, for example, in U.S. Pat. No. 7,587,704, which is incorporated by reference in its entirety. The objective of the simulation is to predict, for example, edge placement, aerial image intensity slope or CD, which can then be compared against an intended design. The intended design is generally defined as a pre-OPC (optical proximity corrected) design layout which can be provided in a standardized digital file format such as GDSII or OASIS or other file format.

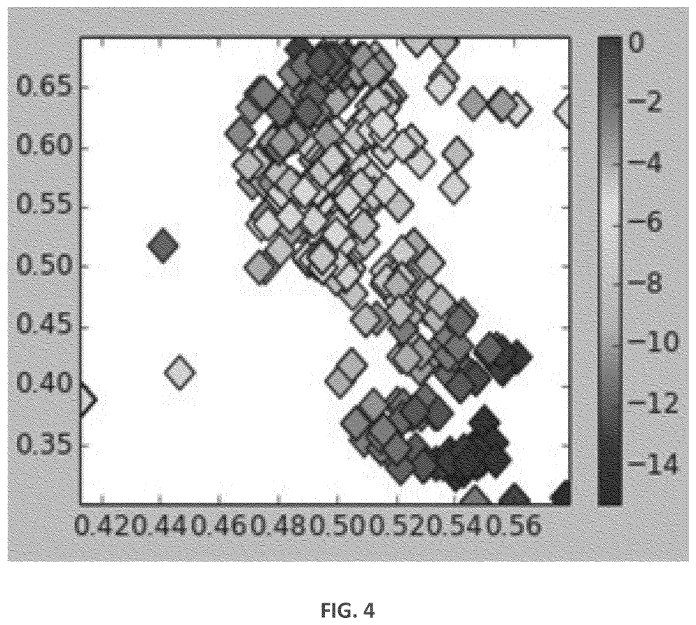

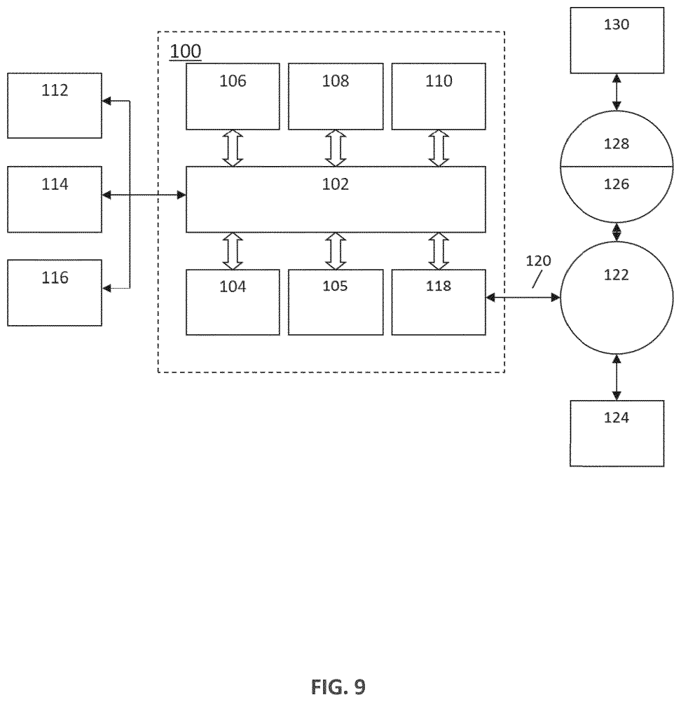

In some embodiments, the pipeline of FIG. 2 may be executed by one or more of the computers described below with reference to FIG. 9, e.g., in a compute cluster described with reference to FIG. 4. In some embodiments, the pipeline of FIG. 2 may be used to augment a reticle with both optical proximity correction and etch-assist features. Software tools for computational analyses of design layouts are available from Brion Technologies Inc. of 4211 Burton Drive, Santa Clara, Calif. 95054, USA, such as software for optical proximity correction, process-window optimization, or source-mask optimization, like Brion's Tachyon line of products.

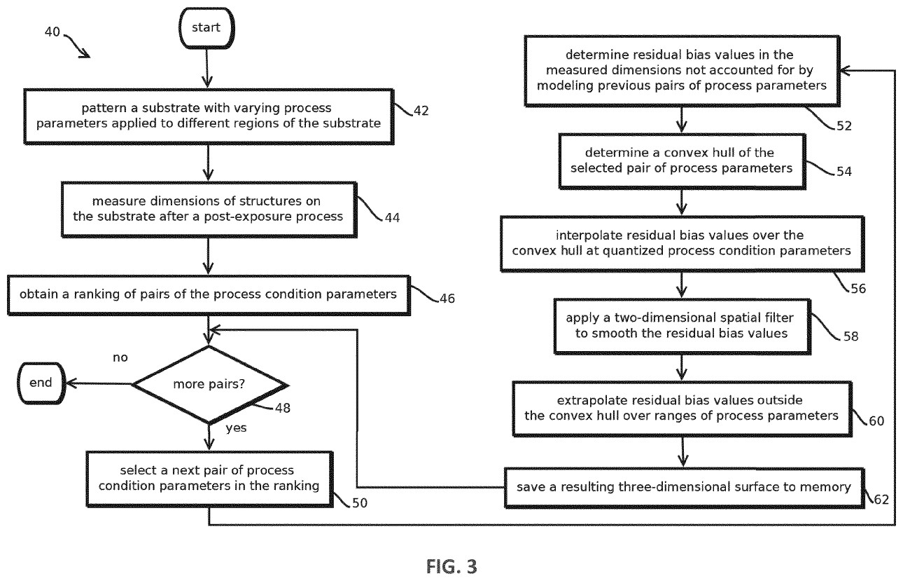

As shown in FIG. 3, some embodiments include a process 40 configured to model the effect of post-exposure processes on the dimensions (e.g., shape, bias, length, width, curvature, and the like, in some cases referred to as critical dimensions) of structures formed on a substrate. In some cases, the post-exposure processes include developing resist to produce structures in resist selectively exposed to energy by a lithographic process. In some cases, the post-exposure processes include etching a layer underlying patterned resist. In some cases, the post-exposure processes include an etch step masked by the patterned resist. Some modeled etches are multistep etches, such as an etch of a hard mask layer underlying a layer of patterned resist, followed by an etch of a layer underlying the hard mask with a second etch process.

Following these processes, various structures may be formed of the substrate, and the dimensions of those structures may depend upon various parameters of the processes, including parameters of the lithography process, resist development, and various etch steps. In some cases, some of the effects are pattern dependent, for instance, depending upon the local or longer-range structures patterned onto a substrate. In some cases, some parameters are pattern independent, such as parameters pertaining to underlying chemistries, laser intensity, plasma energies, and the like.

In some cases, the model may be formed based on empirical calibration data, for example, data obtained by patterning a set of substrates under varying process conditions, corresponding to varying process parameters, and measuring the resulting structures after various posts-exposure processes. The resulting measurements and corresponding process parameters may then be used to form (e.g., train, calibrate, or configure) a model that predicts various measurements likely to result from input sets process parameters. The model may be used for a variety of purposes, including adjusting a mask to counteract various biases arising in post-exposure processes, feedback process control, and process window optimization.

In some embodiments, the operations of the processes 40, and the other processes described herein, may be performed in a different order from that depicted, operations may be added, operations may be omitted, or multiple instances of operations may be executed concurrently (for instance, in multiple computing devices on subsets of the data to expedite operations), none of which is to suggest that other features described herein are not also amenable to variation. In some embodiments, instructions for performing the processes herein may be encoded on a tangible, non-transitory, machine-readable medium such that when the instructions are executed by one or more computers (like that of FIG. 9), the operations described herein are effectuated.

In some embodiments, the process 40 may be performed when designing or refining a design layout pattern to be written to a mask, such that the mask layout may be adjusted to reduce various biases predicted by a model resulting from the process 40.

In some embodiments, the process 40 begins with patterning a substrate with varying process parameters applied to different regions of the substrate, as indicated by block 42. In some cases, patterning a substrate may include patterning a plurality of substrates, for instance varying the process parameters across the different substrates. In some embodiments, patterning the substrate may include varying the process parameters on different regions of the different substrates differently. In some cases, process parameters may be varied within a patterned layout, like in a matrix of test structures in a extant mask.

Various pattern-specific process parameters may be systematically varied, like feature density, line width, line pitch, via sizes, sub-resolution assist features, and the like. Similarly, various pattern independent features may also be varied, for instance across substrates, or in some cases within a substrate, for example by adjusting lithography parameters on an exposure field by exposure field basis and adjusting post-exposure processes to have a gradient across the wafer. In some cases, a relatively large number of process parameters may be varied, and in some cases, the variation may be the result of natural process variation, intentional process variation, or a combination thereof. In some cases, the process parameters may be varied through a range according to predetermined increments, or in some embodiments, the process parameters may vary according to a stochastic process.

The process parameters may take a variety of forms. In some cases, the parameters are terms in the various models for predicting the effect of after exposure processes on resulting structures on a substrate. Examples of such parameters include the following: an acid distribution amount at a location in a pattern; an acid diffusion amount at a location in the pattern; an amount of adjacent pattern-feature influence on acid diffusion amount; an amount of pattern loading effects over a first distance; an amount of pattern density effects over a second distance, the second distance being smaller than the first distance; a parameter of a Gaussian filter; an amount of aerial image intensity; an amount of areal image diffusion; an amount of acid concentration after neutralization; and an amount of base concentration after neutralization. Embodiments may vary two or more, three or more, four or more, five or more, six or more seven or more, eight or more, nine or more, or ten or more of these and other process parameters.

As noted above, patterning a substrate with the varying process parameters may include patterning the substrate with a lithographic process, examples of which are described above and below. In some cases, the lithographic process is a photolithographic process, but embodiments are consistent with the various other patterning processes, such as those described. In some cases, patterning the substrate may include patterning the substrate with post-exposure processes, like developing resist and etches after developing the resist, including soft and hard mask etches.

Some embodiments may include measuring dimensions of structures on the substrate after a post-exposure process, as indicated by block 44. In some cases, the measured dimensions may be measured with a scanning electron microscope, a profilometer (like an atomic force profilometer), or the measure dimensions may be measured according to optical techniques, such as with scatterometery. In some embodiments, the measurements may be measurements of critical dimensions. In some cases, the measurements may be deviations from a target dimension, like a bias in a critical dimension, such as a critical dimension that is narrower than a target, wider than a target, has a sidewall slope different from a target, has a sidewall roughness different from a target, or a misalignment to a target location. In some cases, the measurements obtained may be associated in memory with the set of process parameters that yielded the resulting structure. For instance, some embodiments may measure several hundred or several thousand dimensions, and the set of measurements may be associated with a plurality of process parameters applied to produce the structure that was measured, such as more than two process parameters, more than four process parameters, and in many commercially relevant use cases, six or more, like 10 process parameters.

In some embodiments, the measure dimensions may be a measured dimensions of multiple post-exposure processes, such as measurements taken after developing resist on a given substrate; a different set of measurements may be taken after the same substrate is subject to a hard mask etch; and then a third set of measurements may be taken after that same substrate is subject to an etch of a layer underlying the hard mask. Or, some embodiments may measure such dimensions on different substrates for different post-exposure processes or only one process.

Some embodiments of process 40 may include obtaining a ranking of pairs of the process parameters, as indicated by block 46. In some cases, the pairs of process parameters may be ranked according to the expected magnitude of effects on measure dimensions by the process parameters in the respective pair, either individually or through interaction. In some cases, this ranking may be supplied by an engineer based on experience with the processes being characterized. In some embodiments, this ranking may be determined empirically, for example by performing principal component analysis on a set of measurement data produced with the operations of blocks 42 and 44. In some embodiments, the magnitude of effects on measured dimensions may be a difference between a minimum and a maximum over a range in which the process parameters are varied. Some embodiments may rank the pairs of process parameters in order of decreasing magnitude of effect, such that those with a larger effect are processed first in subsequent operations.

In some embodiments, every pairwise combination of the process parameters may be included in the ranking Or some embodiments may exclude those pairwise combinations expected to have a magnitude of an effect on the measured dimensions less than a threshold amount or those pairs below a threshold rank, like below two, four, five, eight, or ten pairs. In some embodiments, the pairs may be pairs in which no given process parameter repeats between the pairs, or in some embodiments, a given process parameter may appear multiple times in the pairs, such as a process parameter having relatively strong interactions with various other process parameters. In some cases, the ranking may be adjusted in response to cross validation analyses described below.

Block 46 and subsequent operations are described with reference to pairs of process parameters, but it should be understood that the present techniques may be applied to larger sets of process parameters, such as combinations of three process parameters, four process parameters, five process parameters, or more process parameters, depending upon trade-offs between computational complexity, the risk of over fitting, and the power of the model to generalize. Thus, some embodiments may obtain rankings of sets of three process parameters (e.g., every combination or those that satisfy a threshold) according to the magnitude of the effect of those three process parameters, including interactions therebetween, on measured structures on substrates. In some embodiments, these sets may be arranged in memory in an ordered list (e.g., a tuple) of process parameter sets.

Next, some embodiments may iterate through the pairs (or other sets) of process parameters, for instance, in order of rank from highest-ranking to lowest rank, i.e., from those having the largest expected magnitude of effects, to those expected to have the smallest. Some embodiments may include in such iterations a determination of whether there are more pairs in the ranking to be analyzed, as indicated by block 48. Upon determining that there are no more pairs remaining, the process may terminate.

Alternatively, upon determining that there are more pairs of the ranking that have not yet been processed, some embodiments may select a next pair of the process parameters in the ranking, as indicated by block 50. This may include incrementing a counter that counts through the ranking, from a highest ranking process parameter pair to a lowest ranking process parameter pair.

FIG. 4 illustrates an example of measured bias and a pair of process parameters that correspond to the measurements. Bias, in this example, is represented as color or greyscale. Thus, the figure illustrates a three dimensional dataset, where two dimensions correspond to a pair of varied process parameters, and the third dimension corresponds to measured bias of a critical dimension on a test substrate. It is on data such as this that some embodiments may perform subsequently described operations.

Next, some embodiments may determine residual bias values in the measured dimension not accounted for by modeling previous pairs of process parameters, as indicated by block 52. In some embodiments, the first pair of process parameters selected may result in block 52 determining a bias values, rather than a residual bias value. In some embodiments, the modeling of the previous pairs may arise as a result of steps described below, and those models may be saved to memory and retrieved. In some embodiments, those models may result in one or more three or higher dimensional surfaces, in which the dimensions are either process parameters or measure dimensions, like bias. While the steps are described with reference to bias, it should be understood that the technique applies to other values by which the structures on a substrate may be characterized. This may include electrical or optical properties of the structure.

In some embodiments, to determine the residual bias, some embodiments may determine whether the selected pair of process parameters are the first part pair of process parameters in the ranking, in which case of the residual bias may be the measured bias without regard to previously modeled pairs, as such pairs may not have been previously modeled. Alternatively, upon determining that the selected pair is not the first pair in the ranking, some embodiments may retrieved from memory one or more of these three or higher dimensional surfaces from memory, each corresponding to one of the previously modeled pairs (or larger sets of process parameters). Then some embodiments may iterate through those models according to the ranking of step 46, and some embodiments may combine the values in the dimension of the surfaces predicting bias. Some embodiments may compare the resulting predicted sum of bias to the measured bias to obtain residual bias values (e.g., differences between what the model currently addresses and what was actually measured, like measures of model error or fitness). Thus, in some cases, some, and in some cases each and every, measurement obtained in step 44 may be converted into a residual measurement value not yet accounted for in the model.

Next, some embodiments may determine a convex hull of the selected pairs of process parameters, as indicated by block 46. Or, in some embodiments, a concave hull or other type of hull may be determined. To determine the concave hull, some embodiments may determine a polygon that bounds the pairs of process parameters and minimizes an area contained by the polygon (or approximates a minimum), e.g., by determining a convex hull and then iteratively removing a longest edge of the hull to collapse the edge inward to a plurality of edges extending between points spanned by the removed edge. In some cases, the hull may be a convex hull in a set of dimensions that exclude the measurement dimensions from step 44 but include the dimensions corresponding to the process parameters, such as a convex hull exclusively within the process parameter space, or a convex hull in a parameter space that excludes the measured dimension. Or in some cases, the convex hull may include each of these dimensions. In some embodiments, the convex hull may be determined before entering the presently described loop, and the same convex hull may be retrieved from memory and applied in multiple instances.

In some embodiments, determining a convex hull may include executing a Jarvis march algorithm, a Graham scan, a Quickhull algorithm, a Divide and conquer algorithm, a Monotone chain algorithm, an Incremental convex hull algorithm, Chan's algorithm, or the like. In some cases, bounding areas may be determined based on angles between points of varied process parameters (e.g., a process-parameter vector in the dimensions of the varied process parameters). Some embodiments may select a process-parameter vector, such as the lowest process-parameter vector in each dimension, and then determine an angle formed by that process-parameter vector and each of the other process-parameter vectors. The process-parameter vectors may then be sorted according to this angle. Embodiments may then iterate through the sorted sequence to determine whether a line between the two points preceding a given iteration indicate a left turn or a right turn. Upon determining that a left turn has incurred, the line between the points may be designated as indicating a portion of the convex hull.

Or in another example, an embodiment may select the process-parameter vector according to a given dimension among the process-parameter vectors, determine the angle between that process-parameter vector and each of the other process-parameter vectors, and select a largest or smallest angle as indicating a portion of the convex hull. Embodiments may then proceed along that angled line to the other process-parameter vectors and repeat the process, wrapping around the convex hull, until the first process-parameter vector is encountered. Some embodiments may produce a set of vertices corresponding to process parameter coordinates that encompass the test data.

Next, some embodiments may interpolate residual bias values over the convex hull, e.g., at quantized process parameter values. For example, a grid corresponding to the pair of process parameters may be formed in memory, with process parameter values varying through a range at regular, quantized, increments, according to the grid, and some embodiments may interpolate between the process parameters that were applied when patterning the substrate to the quantized process parameters. For example, a given process parameter may be quantized to range from 0 to 10 by increments of one. In this example, some embodiments may have residual bias values of 18 Å for a process parameter of 4.5, and a residual bias value of 22 Å for a process parameter value of 5.5. Some embodiments may interpolate, for example linearly, to calculate a value for the quantized process parameter value therebetween at five, for example, designating the interpolated residual bias value for the quantized process parameter to be 20 Å. In some cases, higher order interpolations may be performed, such as according to a first and second derivative of the residual bias, in some cases, according to partial derivatives including multiple quantized process parameters. In some cases, though, linear interpolation is expected to yield relatively fast results with available computing results resources, while providing adequate accuracy, which is not to suggest that embodiments are not also consistent with more computationally intensive approaches.

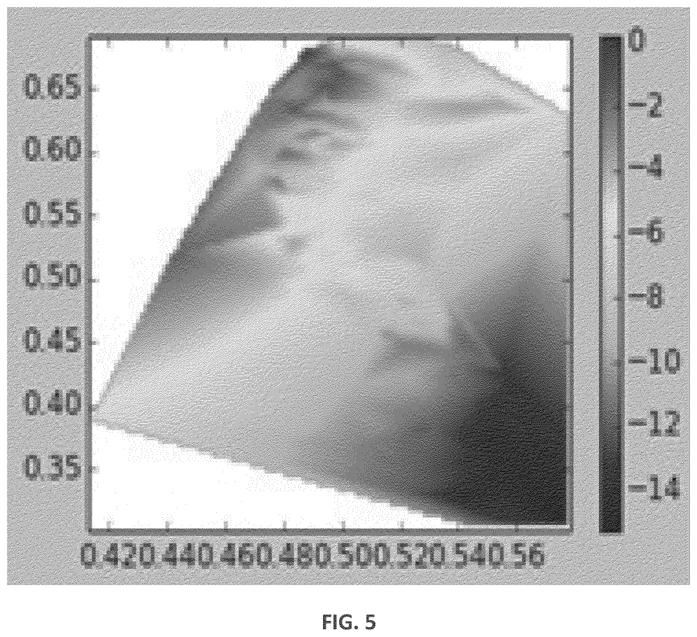

FIG. 5 shows an example of a result of quantizing and interpolating the data structure of FIG. 4. As with FIG. 4, color or greyscale indicates bias (or residual bias), and position indicates process parameter values.

Next, some embodiments may apply a two-dimensional spatial filter to smooth the residual bias values, as indicated by block 58. In some embodiments, this may include changing the interpolated residual bias values to be a local average, such as the average of the residual bias values corresponding to quantized process parameters within plus-or-minus one increment, two increments, five increments, ten increments, or more, depending upon the amount of smoothing desired, and the risk of suppressing meaningful signals. Some embodiments may apply higher dimensional spatial filters, for example, the number of dimensions the special feature filter may correspond to the size of the set of process parameters obtained in block 46.

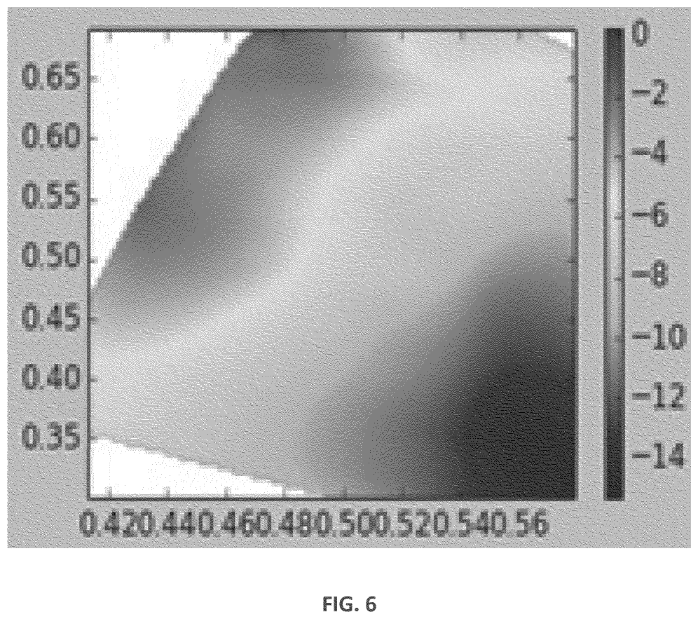

In some embodiments, applying the spatial filter may include performing a convolution on the residual bias values with a kernel that tends to make adjacent values more similar, such as an average of interpolated residual bias values within some threshold distance, or some embodiments may apply other kernel functions, such as those that diminish the effect of more distant interpolated residual bias values, for example, according to a Gaussian kernel. In some cases, before such a convolution, some embodiments may filter the measurements, e.g., to exclude those having values that are different from adjacent values by more than a threshold amount, e.g., more than three standard deviations from a mean of values within plus-or-minus three increments in each process parameter dimension. As a result, some embodiments may make the interpolated residual bias values to be more similar to those adjacent the residual bias values than was the case before the operation of block 58 is performed. An example of a resulting data structure is shown in FIG. 6, which illustrates the result of a local average applied to the data structure of FIG. 5. As with FIG. 4, color or greyscale indicates bias (or residual bias), and position indicates process parameter values.

Next, some embodiments may extrapolate residual bias values outside the convex hull over ranges of process parameters, as indicated by block 16. For example, some embodiments may extrapolate between a minimum value of the process parameter in the convex hull and a maximum value of the process parameter in the convex hull, thereby forming, for example in a two-dimensional process parameter grid, a square or rectangular two-dimensional area over which residual bias values (or for the first pair in the ranking of block 46, the bias values) are interpolated and extrapolated.

In some cases, extrapolation may include designating values corresponding to bias or residual bias outside the convex hull to be equal to a closest value within the convex hull, for instance closest in one of the two dimensions of the process parameters, or a closest by Euclidean distance. Or some embodiments may extrapolate according to a first or second derivative (e.g., a set of partial derivatives) at an edge of the convex hull. In some embodiments, extrapolating may include smoothing a juncture between these extrapolated values in the interpolated values, for example with a spline operation, like a cubic spline.

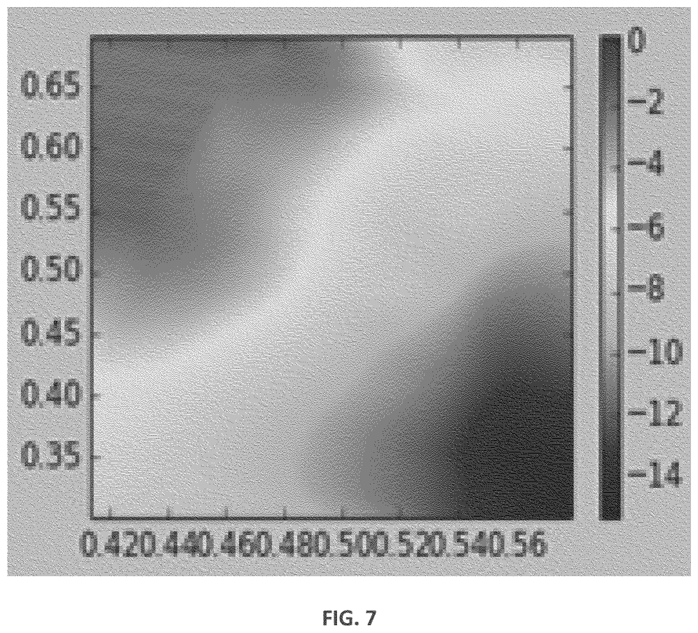

In some cases, the result of step 60 is a three or higher dimensional surface, where one of the dimensions corresponds to bias or residual bias, and the other dimensions correspond to process parameters. In some cases, the surface may have a rectangular, hyper rectangular, or other shape with orthogonal sides in the process parameter dimensions. An example of a resulting data structure is shown in FIG. 7, which illustrates the result of extrapolation applied to the data structure of FIG. 6. As with FIG. 4, color or greyscale indicates bias (or residual bias), and position indicates process parameter values.

Some embodiments may save the resulting three (or higher) dimensional surface to memory, as indicated by block 62. In some cases, saving the service to memory may include saving a matrix to memory, such as a three-dimensional matrix in which one dimension corresponds to bias or residual bias, and the other dimensions correspond to quantized process parameters, like process parameters varying by a fixed increment over a range of values. In some embodiments, the matrix may be characterized as a lookup table, by which the process parameters may serve as index values used to access a value in the bias or residual bias dimension, thereby indicating for a given set of process parameters, an expected amount of bias or residual bias. (It is important to note that data structures need not be labeled as a matrix in program code to constitute a matrix, provided that that structures are logically equivalent to a matrix.) Thus, some embodiments may form a model that characterizes bias or residual bias as a result of process parameters in non-closed form, for example, without encoding the model in the form of an equation, though embodiments are also consistent with fitting an equation to the resulting surface or the underlying data.

Next, the process may return to block 48, and iterations of the above described loop may be repeated until all the pairs have been processed, and a plurality of resulting three or higher dimensional surfaces (for example encoded as three or higher dimensional matrices), have been stored in memory. In some cases, each of these surfaces may be associated with the set of process parameters, such as a process parameter matrix, by which the bias or residual bias dimension is indexed and value indicating a position in a sequence of the surfaces.

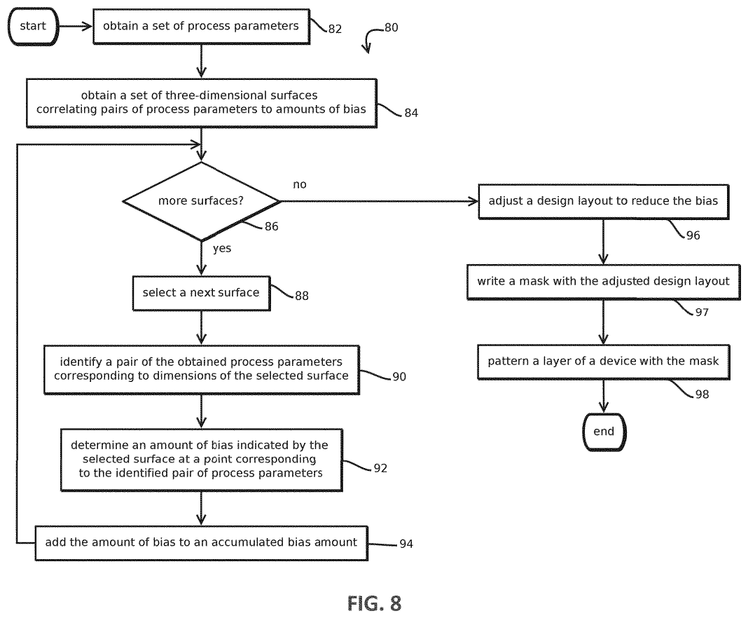

FIG. 8 illustrates an example of a process 80 that may use one or more of the above-described models, for instance, to adjust a design layout of a mask to reduce bias, and in some cases, construct various devices having layers patterned with the mask, like integrated circuit devices, microelectromechanical devices, and optical devices.

In some embodiments, the process 88 includes obtaining a set of process parameters, as indicated by block 82. In some cases, the set of process parameters may be process parameters of a candidate design layout, for instance, combined with a specification for various post-exposure processes.

Next, some embodiments may obtain a set (e.g., an ordered list) of three (or higher) dimensional surfaces correlating pairs of process parameters to amounts of bias (or other dimensions), as indicated by block 84. In some embodiments, this may include obtaining sets of even higher dimensional surfaces correlating larger sets of process parameters to amounts of bias, and in some cases, the amount of bias is a bias or a residual bias relative to other surfaces in the three-dimensional set. In some cases, the set of surfaces may be combined with a ranking or sequence order, such as according to the ranking described above with reference to block 46. Some embodiments may iterate through this sequence to determine an aggregate (e.g., summed) amount of bias predicted for the set of process parameters for a given post-exposure process.

To this end, some embodiments may determine whether there are more surfaces in the set obtained in block 84 that have not yet been processed, as indicated by block 86. Upon determining that there are more surfaces, some embodiments may proceed to select a next surface, as indicated by block 88, for example, according to the sequence order of the set. Next, some embodiments may identify a pair of the obtained process parameters from block 82 corresponding to process parameter dimensions of the selected surface, as indicated by block 80.

Next, some embodiments may determine an amount of bias indicated by the selected surface at a point corresponding to the identified pair of process parameters, as indicated by block 92. In some embodiments, the determined amount of bias is a residual bias relative to previously processed surfaces, such as a sum of biases from previously process surfaces, or the amount of bias is a non-residual bias, for example, for a first surface being processed. In some embodiments, the amount of bias form each surface may be an interpolated bias based on two adjacent quantized process parameter values of the surface and the input process parameters.

Next, some embodiments may add the amount of bias obtained in block 92 to an accumulated bias amount, as indicated by block 94. In some cases, the accumulated bias amount may be initialized to zero, for example, before processing any surfaces. Some embodiments may add an amount of bias predicted from each processed surface to the accumulated bias amount to develop a running total amount of bias corresponding to the set of process parameters.

Next, some embodiments may return to block 86 and determine whether there more surfaces to process. In some cases, this iteration may repeat a number of times, for example, according to a number of surfaces in a model.

Alternatively, some embodiments may proceed to use the resulting accumulated bias amount to make various improvements to a patterning process. For example, some embodiments may adjust a design layout to reduce the bias, as indicated by block 96. For instance, a particular set of process parameters may yield a model prediction that a particular structure in a design layout is likely to have a critical dimension 10 Å narrower the desired dimension as a result of biases arising during resist develop or etch or both, for instance, indicated by the accumulated bias amount from step 94 after the completion of each of the iterations described above. To reduce that bias, some embodiments may make a portion of a mask by which the critical dimension is patterned wider to counteract the predicted bias in the structure after the post-exposure process that was modeled. In some cases, different process parameters may correspond to different portions of a given design layout, for example different portions having different feature densities, line widths, and the like, and different adjustments may be made to different portions of the design layout. In some embodiments, these adjustments may be made concurrent with or before or after performing techniques like optical proximity correction to further enhance the effectiveness of a mask. Next, some embodiments may write a mask with the adjusted design layout, as indicated by block 97, and pattern a layer of a device with the mask, as indicated by block 98. In some cases, patterning a layer may include forming an integrated circuit, an optical device, or a micro electromechanical device, for instance, with semiconductor patterning technology, like in a semiconductor fab.

Thus, some embodiments may improve upon semiconductor manufacturing technology by modeling post exposure processes, and in some cases, these models may account for interactions between process parameters. In some embodiments, some resultant models may be relatively resistant to over fitting, and some models may mitigate the computational complexity arising from processes that account for an excessive number of interactions.

In some embodiments, models may be validated. For example some embodiments may cross validate models by withholding a portion of the measured dimensions of structures obtained a block 44 of FIG. 3 during the process of forming the models. For example, some embodiments may randomly sample a percentage, like 10% or 5% of the measurements to be withheld. Some embodiments may then test the resulting models by predicting amounts of bias for process parameters corresponding to the measured dimensions that were withheld, and those predicted values may be compared to the measured dimensions to determine differences between predictions and observations. Some embodiments may aggregate these differences, for example, by determining an average absolute difference amount. Some embodiments may compare this aggregate value to a threshold to determine whether the obtain model is sufficiently accurate.

FIG. 9 is a block diagram that illustrates a computer system 100 that may assist in implementing the simulation, characterization, and qualification methods and flows disclosed herein. Computer system 100 includes a bus 102 or other communication mechanism for communicating information, and a processor 104 (or multiple processors 104 and 105) coupled with bus 102 for processing information. Computer system 100 also includes a main memory 106, such as a random access memory (RAM) or other dynamic storage device, coupled to bus 102 for storing information and instructions to be executed by processor 104. Main memory 106 also may be used for storing temporary variables or other intermediate information during execution of instructions to be executed by processor 104. Computer system 100 further includes a read only memory (ROM) 108 or other static storage device coupled to bus 102 for storing static information and instructions for processor 104. A storage device 110, such as a magnetic disk or optical disk, is provided and coupled to bus 102 for storing information and instructions.

Computer system 100 may be coupled via bus 102 to a display 112, such as a cathode ray tube (CRT) or flat panel or touch panel display for displaying information to a computer user. An input device 114, including alphanumeric and other keys, is coupled to bus 102 for communicating information and command selections to processor 104. Another type of user input device is cursor control 116, such as a mouse, a trackball, or cursor direction keys for communicating direction information and command selections to processor 104 and for controlling cursor movement on display 112. This input device typically has two degrees of freedom in two axes, a first axis (e.g., x) and a second axis (e.g., y), that allows the device to specify positions in a plane. A touch panel (screen) display may also be used as an input device.

According to one embodiment, portions of the optimization process may be performed by computer system 100 in response to processor 104 executing one or more sequences of one or more instructions contained in main memory 106. Such instructions may be read into main memory 106 from another computer-readable medium, such as storage device 110. Execution of the sequences of instructions contained in main memory 106 causes processor 104 to perform the process steps described herein. One or more processors in a multi-processing arrangement may also be employed to execute the sequences of instructions contained in main memory 106. In an alternative embodiment, hard-wired circuitry may be used in place of or in combination with software instructions. The computer need not be co-located with the patterning system to which an optimization process pertains. In some embodiments, the computer (or computers) may be geographically remote.

The term “computer-readable medium” as used herein refers to any tangible, non-transitory medium that participates in providing instructions to processor 104 for execution. Such a medium may take many forms, including non-volatile media and volatile media. Non-volatile media include, for example, optical or magnetic disks or solid state drives, such as storage device 110. Volatile media include dynamic memory, such as main memory 106. Transmission media include coaxial cables, copper wire and fiber optics, including the wires or traces that constitute part of the bus 102. Transmission media can also take the form of acoustic or light waves, such as those generated during radio frequency (RF) and infrared (IR) data communications. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, and EPROM, a FLASH-EPROM, any other memory chip or cartridge. In some embodiments, transitory media may encode the instructions, such as in a carrier wave.

Various forms of computer readable media may be involved in carrying one or more sequences of one or more instructions to processor 104 for execution. For example, the instructions may initially be borne on a magnetic disk of a remote computer. The remote computer can load the instructions into its dynamic memory and send the instructions over a telephone line using a modem. A modem local to computer system 100 can receive the data on the telephone line and use an infrared transmitter to convert the data to an infrared signal. An infrared detector coupled to bus 102 can receive the data carried in the infrared signal and place the data on bus 102. Bus 102 carries the data to main memory 106, from which processor 104 retrieves and executes the instructions. The instructions received by main memory 106 may optionally be stored on storage device 110 either before or after execution by processor 104.

Computer system 100 may also include a communication interface 118 coupled to bus 102. Communication interface 118 provides a two-way data communication coupling to a network link 120 that is connected to a local network 122. For example, communication interface 118 may be an integrated services digital network (ISDN) card or a modem to provide a data communication connection to a corresponding type of telephone line. As another example, communication interface 118 may be a local area network (LAN) card to provide a data communication connection to a compatible LAN. Wireless links may also be implemented. In any such implementation, communication interface 118 sends and receives electrical, electromagnetic or optical signals that carry digital data streams representing various types of information.

Network link 120 typically provides data communication through one or more networks to other data devices. For example, network link 120 may provide a connection through local network 122 to a host computer 124 or to data equipment operated by an Internet Service Provider (ISP) 126. ISP 126 in turn provides data communication services through the worldwide packet data communication network, now commonly referred to as the “Internet” 128. Local network 122 and Internet 128 both use electrical, electromagnetic or optical signals that carry digital data streams. The signals through the various networks and the signals on network link 120 and through communication interface 118, which carry the digital data to and from computer system 100, are exemplary forms of carrier waves transporting the information.

Computer system 100 can send messages and receive data, including program code, through the network(s), network link 120, and communication interface 118. In the Internet example, a server 130 might transmit a requested code for an application program through Internet 128, ISP 126, local network 122 and communication interface 118. One such downloaded application may provide for the illumination optimization of the embodiment, for example. The received code may be executed by processor 104 as it is received, and/or stored in storage device 110, or other non-volatile storage for later execution. In this manner, computer system 100 may obtain application code in the form of a carrier wave.

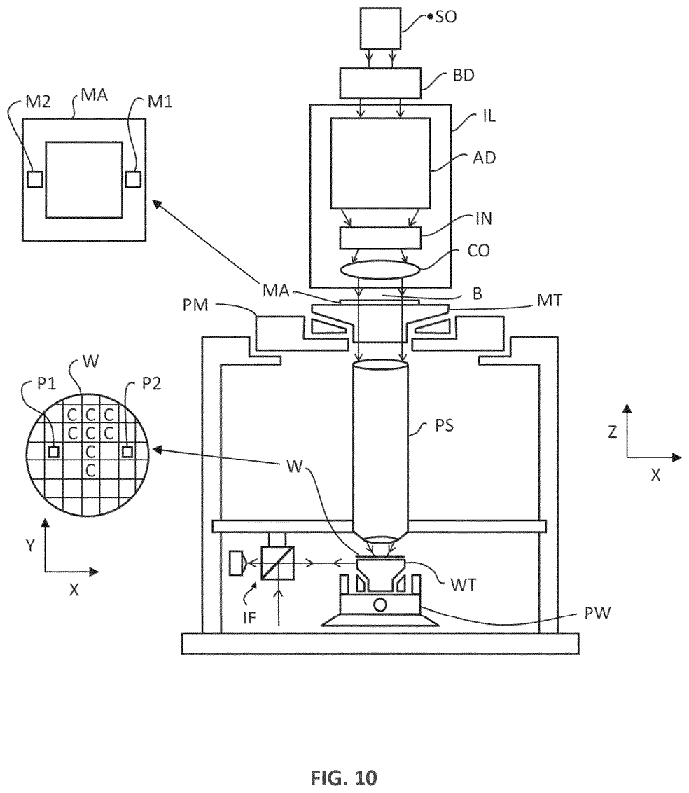

FIG. 10 schematically depicts an exemplary lithographic projection apparatus whose process window for a given process may be characterized with the techniques described herein. The apparatus comprises:
an illumination system IL, to condition a beam B of radiation. In this particular case, the illumination system also comprises a radiation source SO;
a first object table (e.g., patterning device table) MT provided with a patterning device holder to hold a patterning device MA (e.g., a reticle), and connected to a first positioner to accurately position the patterning device with respect to item PS;
a second object table (substrate table) WT provided with a substrate holder to hold a substrate W (e.g., a resist coated silicon wafer), and connected to a second positioner to accurately position the substrate with respect to item PS;
a projection system (“lens”) PS (e.g., a refractive, catoptric or catadioptric optical system) to image an irradiated portion of the patterning device MA onto a target portion C (e.g., comprising one or more dies) of the substrate W.

As depicted herein, the apparatus is of a transmissive type (i.e., has a transmissive patterning device). However, in general, it may also be of a reflective type, for example (with a reflective patterning device). The apparatus may employ a different kind of patterning device to classic mask; examples include a programmable mirror array or LCD matrix.

The source SO (e.g., a mercury lamp or excimer laser, LPP (laser produced plasma) EUV source) produces a beam of radiation. This beam is fed into an illumination system (illuminator) IL, either directly or after having traversed conditioning means, such as a beam expander Ex, for example. The illuminator IL may comprise adjusting means AD for setting the outer and/or inner radial extent (commonly referred to as -outer and -inner, respectively) of the intensity distribution in the beam. In addition, it will generally comprise various other components, such as an integrator IN and a condenser CO. In this way, the beam B impinging on the patterning device MA has a desired uniformity and intensity distribution in its cross section.

It should be noted with regard to FIG. 10 that the source SO may be within the housing of the lithographic projection apparatus (as is often the case when the source SO is a mercury lamp, for example), but that it may also be remote from the lithographic projection apparatus, the radiation beam that it produces being led into the apparatus (e.g., with the aid of suitable directing mirrors); this latter scenario is often the case when the source SO is an excimer laser (e.g., based on KrF, ArF or F2 lasing).

The beam PB subsequently intercepts the patterning device MA, which is held on a patterning device table MT. Having traversed the patterning device MA, the beam B passes through the lens PL, which focuses the beam B onto a target portion C of the substrate W. With the aid of the second positioning means (and interferometric measuring means IF), the substrate table WT can be moved accurately, e.g. so as to position different target portions C in the path of the beam PB. Similarly, the first positioning means can be used to accurately position the patterning device MA with respect to the path of the beam B, e.g., after mechanical retrieval of the patterning device MA from a patterning device library, or during a scan. In general, movement of the object tables MT, WT will be realized with the aid of a long-stroke module (coarse positioning) and a short-stroke module (fine positioning), which are not explicitly depicted in FIG. 10. However, in the case of a stepper (as opposed to a step-and-scan tool) the patterning device table MT may just be connected to a short stroke actuator, or may be fixed.

The depicted tool can be used in two different modes:
In step mode, the patterning device table MT is kept essentially stationary, and an entire patterning device image is projected in one go (i.e., a single “flash”) onto a target portion C. The substrate table WT is then shifted in the x and/or y directions so that a different target portion C can be irradiated by the beam PB;
In scan mode, essentially the same scenario applies, except that a given target portion C is not exposed in a single “flash”. Instead, the patterning device table MT is movable in a given direction (the so-called “scan direction”, e.g., the y direction) with a speed v, so that the projection beam B is caused to scan over a patterning device image; concurrently, the substrate table WT is simultaneously moved in the same or opposite direction at a speed V=Mv, in which M is the magnification of the lens PL (typically, M=1/4 or 1/5). In this manner, a relatively large target portion C can be exposed, without having to compromise on resolution.

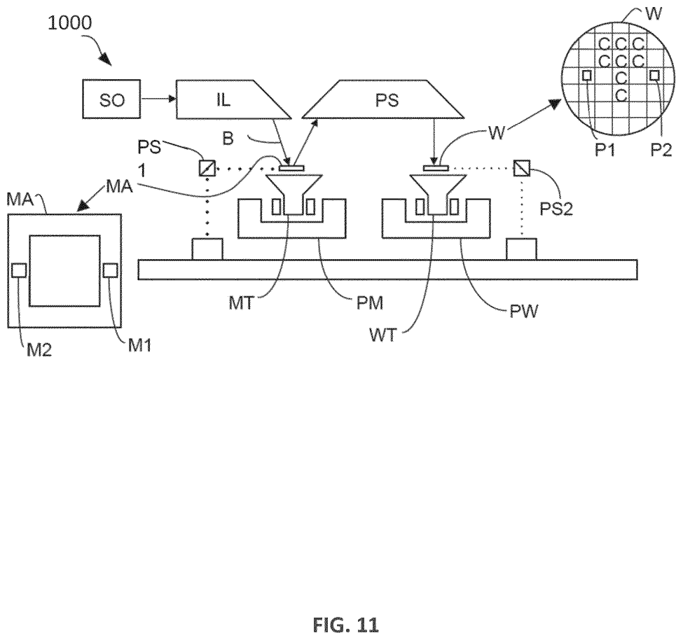

FIG. 11 schematically depicts another exemplary lithographic projection apparatus 1000 whose process window for a given process may be characterized with the techniques described herein.

The lithographic projection apparatus 1000, in some embodiments, includes:
a source collector module SO
an illumination system (illuminator) IL configured to condition a radiation beam B (e.g.

EUV radiation).
a support structure (e.g. a patterning device table) MT constructed to support a patterning device (e.g. a mask or a reticle) MA and connected to a first positioner PM configured to accurately position the patterning device;
a substrate table (e.g. a wafer table) WT constructed to hold a substrate (e.g. a resist coated wafer) W and connected to a second positioner PW configured to accurately position the substrate; and
a projection system (e.g. a reflective projection system) PS configured to project a pattern imparted to the radiation beam B by patterning device MA onto a target portion C (e.g. comprising one or more dies) of the substrate W.

As here depicted, the apparatus 1000 is of a reflective type (e.g. employing a reflective patterning device). It is to be noted that because most materials are absorptive within the EUV wavelength range, the patterning device may have multilayer reflectors comprising, for example, a multi-stack of Molybdenum and Silicon. In one example, the multi-stack reflector has a 40 layer pairs of Molybdenum and Silicon where the thickness of each layer is a quarter wavelength. Even smaller wavelengths may be produced with X-ray lithography. Since most material is absorptive at EUV and x-ray wavelengths, a thin piece of patterned absorbing material on the patterning device topography (e.g., a TaN absorber on top of the multi-layer reflector) defines where features would print (positive resist) or not print (negative resist).

As shown in FIG. 11, in some embodiments, the illuminator IL receives an extreme ultra violet radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the plasma can be produced by irradiating a fuel, such as a droplet, stream or cluster of material having the line-emitting element, with a laser beam. The source collector module SO may be part of an EUV radiation system including a laser, not shown in FIG. 11, for providing the laser beam exciting the fuel. The resulting plasma emits output radiation, e.g., EUV radiation, which is collected using a radiation collector, disposed in the source collector module. The laser and the source collector module may be separate entities, for example, when a CO2 laser is used to provide the laser beam for fuel excitation.

In such cases, the laser is not considered to form part of the lithographic apparatus and the radiation beam is passed from the laser to the source collector module with the aid of a beam delivery system comprising, for example, suitable directing mirrors or a beam expander. In other cases the source may be an integral part of the source collector module, for example when the source is a discharge produced plasma EUV generator, often termed as a DPP source.

The illuminator IL may include an adjuster for adjusting the angular intensity distribution of the radiation beam. Generally, at least the outer or inner radial extent (commonly referred to as σ-outer and σ-inner, respectively) of the intensity distribution in a pupil plane of the illuminator can be adjusted, in some embodiments. In addition, the illuminator IL may include various other components, such as facetted field and pupil mirror devices. The illuminator may be used to condition the radiation beam, to have a desired uniformity and intensity distribution in its cross section.

The radiation beam B is incident on the patterning device (e.g., mask) MA, which is held on the support structure (e.g., patterning device table) MT, and is patterned by the patterning device, in this example. After being reflected from the patterning device (e.g., mask) MA, the radiation beam B passes through the projection system PS, which focuses the beam onto a target portion C of the substrate W. With the aid of the second positioner PW and position sensor PS2 (e.g., an interferometer, linear encoder or capacitive sensor), the substrate table WT can be moved accurately, e.g., so as to position different target portions C in the path of the radiation beam B. Similarly, the first positioner PM and another position sensor PS1 can be used to accurately position the patterning device (e.g. mask) MA with respect to the path of the radiation beam B. Patterning device (e.g. mask) MA and substrate W may be aligned using patterning device alignment marks M1, M2 and substrate alignment marks P1, P2.

The depicted apparatus 1000 may be used in at least one of the following modes:

1. In step mode, the support structure (e.g. patterning device table) MT and the substrate table WT are kept essentially stationary, while an entire pattern imparted to the radiation beam is projected onto a target portion C at one time (i.e. a single static exposure). The substrate table WT is then shifted in the X and/or Y direction so that a different target portion C can be exposed.
2. In scan mode, the support structure (e.g. patterning device table) MT and the substrate table WT are scanned synchronously while a pattern imparted to the radiation beam is projected onto a target portion C (i.e. a single dynamic exposure). The velocity and direction of the substrate table WT relative to the support structure (e.g. patterning device table) MT may be determined by the (de-)magnification and image reversal characteristics of the projection system PS.
3. In another mode, the support structure (e.g. patterning device table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that uses programmable patterning device, such as a programmable mirror array of a type as referred to above.

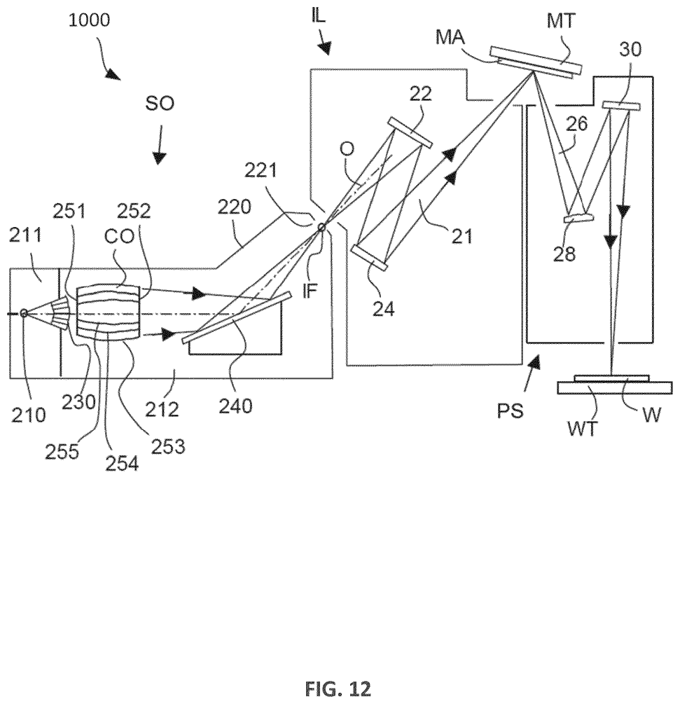

FIG. 12 shows the apparatus 1000 in more detail, including the source collector module SO, the illumination system IL, and the projection system PS. The source collector module SO is constructed and arranged such that a vacuum environment can be maintained in an enclosing structure 220 of the source collector module SO. An EUV radiation emitting plasma 210 may be formed by a discharge produced plasma source. EUV radiation may be produced by a gas or vapor, for example Xe gas, Li vapor or Sn vapor in which the very hot plasma 210 is created to emit radiation in the EUV range of the electromagnetic spectrum. The very hot plasma 210 is created by, for example, an electrical discharge causing an at least partially ionized plasma. Partial pressures of, for example, 10 Pa of Xe, Li, Sn vapor or any other suitable gas or vapor may be required for efficient generation of the radiation. In an embodiment, a plasma of excited tin (Sn) is provided to produce EUV radiation.

The radiation emitted by the hot plasma 210 is passed from a source chamber 211 into a collector chamber 212 via an optional gas barrier or contaminant trap 230 (in some cases also referred to as contaminant barrier or foil trap) which is positioned in or behind an opening in source chamber 211. The contaminant trap 230 may include a channel structure. Contamination trap 230 may also include a gas barrier or a combination of a gas barrier and a channel structure. The contaminant trap or contaminant barrier 230 further indicated herein at least includes a channel structure, as known in the art.

The collector chamber 211 may include a radiation collector CO which may be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point IF along the optical axis indicated by the dot-dashed line ‘O’. The virtual source point IF is commonly referred to as the intermediate focus, and the source collector module is arranged such that the intermediate focus IF is located at or near an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21, at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the substrate table WT.

More elements than shown may generally be present in illumination optics unit IL and projection system PS. The grating spectral filter 240 may optionally be present, depending upon the type of lithographic apparatus. Further, there may be more mirrors present than those shown in the figures, for example there may be 1-6 additional reflective elements present in the projection system PS than shown in FIG. 12.

Collector optic CO, as illustrated in FIG. 12, is depicted as a nested collector with grazing incidence reflectors 253, 254 and 255, just as an example of a collector (or collector mirror). The grazing incidence reflectors 253, 254 and 255 are disposed axially symmetric around the optical axis O and a collector optic CO of this type may be used in combination with a discharge produced plasma source, often called a DPP source.

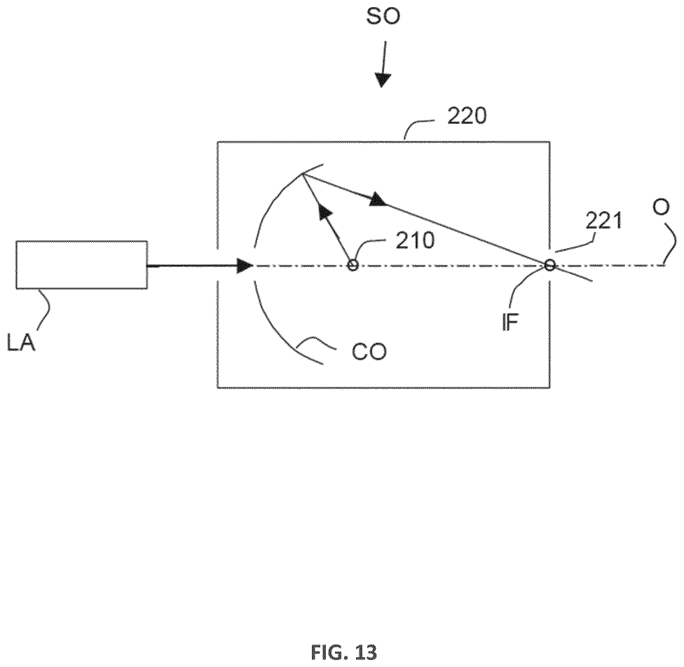

Alternatively, the source collector module SO may be part of an LPP radiation system as shown in FIG. 13. A laser LA is arranged to deposit laser energy into a fuel, such as xenon (Xe), tin (Sn) or lithium (Li), creating the highly ionized plasma 210 with electron temperatures of several 10's of eV. The energetic radiation generated during de-excitation and recombination of these ions is emitted from the plasma, collected by a near normal incidence collector optic CO and focused onto the opening 221 in the enclosing structure 220.**

The embodiments may further be described using the following clauses:

1. A method of modeling post-exposure effects in patterning processes, the method comprising: obtaining, with one or more processors, values based on measurements of structures formed on one or more substrates by a post-exposure process and values of a first pair of process parameters by which process conditions were varied; modeling, with one or more processors, as a surface, correlation between the values based on measurements of the structures and the values of the first pair of process parameters; and storing, with one or more processors, the model in memory.
2. The method of clause 1, wherein: the obtained values are bias measurements of critical dimensions of structures patterned on a substrate via lithographic processing; the varied process conditions comprise: pattern-dependent variations within a pattern; varied process conditions of a resist development process; and varied process conditions of an etch process after the resist development process; and modeling comprises constructing a plurality of three or higher dimensional matrices, each matrix having bias amounts or residual bias amounts correlated to values of process parameters of a respective pair of the varied process conditions, at least some of the matrices indicating a residual amount of bias not accounted for by another one of the matrices; the method comprising: after storing the model in memory, obtaining a set of values of process parameters; accessing a plurality of bias amounts in the plurality of matrices correlated to pairs of the set of values of process parameters; and combining the accessed bias amounts into an aggregate bias amount predicted to result under the process parameters after a resist development process and an etch process.
3. The method of any of clauses 1-2, wherein modeling comprises: interpolating corresponding values based on measurements of structures formed on one or more substrates to representative values in a grid; and smoothing the representative values by making at least some of the representative values more similar to an adjacent representative value in the grid.
4. The method of any of clauses 1-3, wherein the model is stored in memory in a data structure in which estimated dimensions of a structure on a substrate are accessible based on given values of the first pair of post-exposure process parameters.
5. The method of clause 4, wherein the model is encoded as a lookup table having post-exposure process parameters as index values to which estimated dimensions of the structure on the substrate are correlated.
6. The method of any of clauses 1-5, wherein the values based on measurements of structures formed on one or more substrates comprise: measured bias amounts of dimensions of structures formed on the one or more substrates.
7. The method of any of clauses 1-6, wherein modeling comprises: determining a hull of the values of the first pair of process parameters.
8. The method of any of clauses 1-7, wherein modeling comprises: interpolating values corresponding to the measurements of structures formed on the one or more substrates between pairs of values of the first pair of process parameters.
9. The method of any of clauses 1-8, wherein modeling comprises: applying a two or higher dimensional spatial filter by convolving values based on measurements of structures formed on the one or more substrates.
10. The method of any of clauses 1-9, wherein modeling comprises smoothing with local averaging values based on measurements of structures formed on the one or more substrates.
11. The method of any of clauses 1-10, wherein modeling comprises: inferring bias amounts of structures for values of the first pair of post exposure process parameters for which measurements of structures on the one or more substrates are not obtained.
12. The method of clause 11, comprising steps for inferring bias amounts where measurements of structures on the one or more substrates are not obtained.
13. The method of any of clauses 1-12, wherein modeling comprises: forming a plurality of non-closed form expressions of correlations of measured bias to respective sets of varied process parameters.
14. The method of any of clauses 1-13, wherein modeling comprises: steps for modeling bias as a function of process parameters.
15. The method of any of clauses 1-14, wherein modeling comprises: modeling a plurality of sets of process parameters as a plurality of respective surfaces.
16. The method of any of clauses 1-15, wherein the post-exposure process is a resist development process.
17. The method of any of clauses 1-16, wherein the post-exposure process is an etch processes.
18. The method of any of clauses 1-17, wherein the process parameters include at least six process parameters selected from the following: an acid distribution amount at a location in a pattern; an acid diffusion amount at a location in the pattern; an amount of adjacent pattern-feature influence on acid diffusion amount; an amount of pattern loading effects over a first distance; an amount of pattern density effects over a second distance, the second distance being smaller than the first distance; a parameter of a Gaussian filter; an amount of aerial image intensity; an amount of areal image diffusion; an amount of acid concentration after neutralization; and an amount of base concentration after neutralization.
19. The method of any of clauses 1-18, comprising: adjusting a design layout based on the model stored in memory; and constructing an integrated circuit, optical device, or microelectromechanical device on a substrate by patterning a layer of the device with the adjusted design layout.
20. The method of any of clauses 1-19, wherein modeling comprises: determining a convex hull of the values of the first pair of process parameters.
21. A tangible, non-transitory, machine-readable medium storing instructions that when executed by a data processing apparatus cause the data processing apparatus to perform operations comprising: the operations of any of clauses 1-20.
22. A system, comprising: one or more processors; and memory storing instructions that when executed by the processors cause the processors to effectuate operations comprising: the operations of any of clauses 1-20.

U.S. Patent Application Publication No. US 2013-0179847 is hereby incorporated by reference in its entirety.

The concepts disclosed herein may simulate or mathematically model any generic imaging system for imaging sub wavelength features, and may be especially useful with emerging imaging technologies capable of producing increasingly shorter wavelengths. Emerging technologies already in use include EUV (extreme ultra violet), DUV lithography that is capable of producing a 193 nm wavelength with the use of an ArF laser, and even a 157 nm wavelength with the use of a Fluorine laser. Moreover, EUV lithography is capable of producing wavelengths within a range of 20-5 nm by using a synchrotron or by hitting a material (either solid or a plasma) with high energy electrons in order to produce photons within this range.

The reader should appreciate that the present application describes several inventions. Rather than separating those inventions into multiple isolated patent applications, applicants have grouped these inventions into a single document because their related subject matter lends itself to economies in the application process. But the distinct advantages and aspects of such inventions should not be conflated. In some cases, embodiments address all of the deficiencies noted herein, but it should be understood that the inventions are independently useful, and some embodiments address only a subset of such problems or offer other, unmentioned benefits that will be apparent to those of skill in the art reviewing the present disclosure. Due to costs constraints, some inventions disclosed herein may not be presently claimed and may be claimed in later filings, such as continuation applications or by amending the present claims. Similarly, due to space constraints, neither the Abstract nor the Summary of the Invention sections of the present document should be taken as containing a comprehensive listing of all such inventions or all aspects of such inventions.

It should be understood that the description and the drawings are not intended to limit the invention to the particular form disclosed, but to the contrary, the intention is to cover all modifications, equivalents, and alternatives falling within the spirit and scope of the present invention as defined by the appended claims. Further modifications and alternative embodiments of various aspects of the invention will be apparent to those skilled in the art in view of this description. Accordingly, this description and the drawings are to be construed as illustrative only and are for the purpose of teaching those skilled in the art the general manner of carrying out the invention. It is to be understood that the forms of the invention shown and described herein are to be taken as examples of embodiments. Elements and materials may be substituted for those illustrated and described herein, parts and processes may be reversed or omitted, and certain features of the invention may be utilized independently, all as would be apparent to one skilled in the art after having the benefit of this description of the invention. Changes may be made in the elements described herein without departing from the spirit and scope of the invention as described in the following claims. Headings used herein are for organizational purposes only and are not meant to be used to limit the scope of the description.

As used throughout this application, the word “may” is used in a permissive sense (i.e., meaning having the potential to), rather than the mandatory sense (i.e., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, i.e., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, i.e., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X'ed items,” used for purposes of making claims more readable rather than specifying sequence. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device.

In this patent, certain U.S. patents, U.S. patent applications, or other materials (e.g., articles) have been incorporated by reference. The text of such U.S. patents, U.S. patent applications, and other materials is, however, only incorporated by reference to the extent that no conflict exists between such material and the statements and drawings set forth herein. In the event of such conflict, the text of the present document governs.

1. A method of modeling post-exposure effects in patterning processes, the method comprising:
obtaining values based on measurements of structures formed on one or more substrates by a post-exposure process and values of a pair of process parameters by which process conditions were varied;
modeling, by a processor system, as a surface, correlation between the values based on measurements of the structures and the values of the pair of process parameters; and
storing the model in memory.

2. The method of claim 1, wherein:
the obtained values based on measurements are bias measurements of critical dimensions of structures patterned on a substrate via lithographic processing;
the varied process conditions comprise:
pattern-dependent variations within a pattern;
varied Process conditions of a resist development process; and/or
varied process conditions of an etch process after the resist development process; and
the modeling comprises constructing a plurality of three or higher dimensional matrices, each matrix having bias amounts or residual bias amounts correlated to values of a process parameter of the pair of process parameters, at least one of the matrices indicating a residual amount of bias not accounted for by another one of the matrices;
the method further comprising:
after storing the model in memory, obtaining a set of values of one or more process parameters;
accessing a plurality of bias amounts in the plurality of matrices correlated to pairs of the set of values of one or more process parameters; and
combining the accessed bias amounts into an aggregate-bias amount predicted to result under the one or more process parameters after a resist development process and an etch process.

3. The method of claim 1, wherein the modeling comprises:
interpolating corresponding values based on measurements of structures formed on one or more substrates to representative values in a grid; and
smoothing the representative values by making at least one of the representative values more similar to an adjacent representative value in the grid.

4. The method of claim 1, wherein the model is stored in memory in a data structure in which estimated dimensions of a structure on a substrate are accessible based on given values of the pair of process parameters.

5. The method of claim 1, wherein the model is encoded as a lookup table having post-exposure process parameters as indexes to which estimated dimensions of the structure on the substrate are correlated.

6. The method of claim 1, wherein the values based on measurements of structures formed on one or more substrates comprise measured bias amounts of dimensions of structures formed on the one or more substrates.

7. The method of claim 1, wherein the modeling comprises determining a hull of the values of the pair of process parameters, wherein determining the hull of the values of the pair of process parameters comprises determining a convex hull of the values of the first pair of process parameters.

8. The method of claim 1, wherein the modeling comprises:
interpolating values corresponding to the measurements of structures formed on the one or more substrates between pairs of values of the pair of process parameters, and/or
applying a two or higher dimensional spatial filter by convolving values based on measurements of structures formed on the one or more substrates, and/or
smoothing with local averaging values based on measurements of structures formed on the one or more substrates.

9. The method of claim 1, wherein modeling comprises inferring bias amounts of structures for values of the pair of post exposure process parameters for which measurements of structures on the one or more substrates are not obtained.

10. The method of claim 1, wherein modeling comprises forming a plurality of non-closed form expressions of correlations of measured bias to respective sets of varied process parameters.

11. The method of claim 1, wherein modeling comprises modeling a plurality of sets of process parameters as a plurality of respective surfaces.

12. The method of claim 1, wherein the post-exposure process is a resist development process, or wherein the post-exposure process is an etch process.

13. The method of claim 1, wherein the process parameters include at least two process parameters selected from:
an acid distribution amount at a location in a pattern;
an acid diffusion amount at a location in the pattern;
an amount of adjacent pattern-feature influence on acid diffusion amount;
an amount of pattern loading effects over a first distance;
an amount of pattern density effects over a second distance, the second distance being smaller than the first distance;
a parameter of a Gaussian filter;
an amount of aerial image intensity;
an amount of areal image diffusion;
an amount of acid concentration after neutralization; and
an amount of base concentration after neutralization.

14. The method of claim 1, further comprising:
adjusting a design layout based on the model stored in memory; and
constructing an integrated circuit, optical device, or microelectromechanical device on a substrate by patterning a layer of the device with the adjusted design layout.

15. (canceled)

16. A non-transitory computer-readable medium comprising instructions therein, the instructions, when executed by a processor system, configured to cause the processor system to at least:
obtain values based on measurements of structures formed on one or more substrates by a post-exposure process and values of a pair of process parameters by which process conditions were varied;
model, as a surface, correlation between the values based on measurements of the structures and the values of the pair of process parameters; and
store the model in memory.

17. The computer-readable medium of claim 16, wherein:
the obtained values based on measurements are bias measurements of critical dimensions of structures patterned on a substrate via lithographic processing;
the varied process conditions comprise:
pattern-dependent variations within a pattern;
varied process conditions of a resist development process; and/or
varied process conditions of an etch process after the resist development process; and
the modeling comprises construction of a plurality of three or higher dimensional matrices, each matrix having bias amounts or residual bias amounts correlated to values of a process parameter of the pair of process parameters, at least one of the matrices indicating a residual amount of bias not accounted for by another one of the matrices; and
the instructions are further configured to cause the computer system to:
after storage of the model in memory, obtain a set of values of one or more process parameters;
access a plurality of bias amounts in the plurality of matrices correlated to pairs of the set of values of one or more process parameters; and
combine the accessed bias amounts into an aggregate bias amount predicted to result under the one or more process parameters after a resist development process and an etch process.

18. The computer-readable medium of claim 16, wherein the modeling comprises:
interpolation of corresponding values based on measurements of structures formed on one or more substrates to representative values in a grid; and
smoothing of the representative values by making at least one of the representative values more similar to an adjacent representative value in the grid.

19. The computer-readable medium of claim 16, wherein the model is stored in memory in a data structure in which estimated dimensions of a structure on a substrate are accessible based on given values of the pair of process parameters.

20. The computer-readable medium of claim 16, wherein the values based on measurements of structures formed on one or more substrates comprise measured bias amounts of dimensions of structures formed on the one or more substrates.

21. The computer-readable medium of claim 16, wherein the modeling comprises:
interpolation of values corresponding to the measurements of structures formed on the one or more substrates between pairs of values of the pair of process parameters, and/or
application of a two or higher dimensional spatial filter by convolving values based on measurements of structures formed on the one or more substrates, and/or
smoothing with local averaging values based on measurements of structures formed on the one or more substrates.
